(19) United States
(12) Patent Application Publication
(10) Pub. No.: US 2024/0198559 A1
(43) Pub. Date: Jun. 20, 2024

(54) METHOD FOR FIXING A MATERIAL BLOCK FOR MECHANICAL MACHINING

(71) Applicant: Fraunhofer-Gesellschaft zur Förderung der angewandten Forschung e.V., München (DE)

(72) Inventors: Hartmut SCHWABE, Halle (Saale) (DE); Ringo KÖPGE, Halle (Saale) (DE)

(73) Assignee: Fraunhofer-Gesellschaft zur Förderung der angewandten Forschung e.V., München (DE)

(21) Appl. No.: 18/286,566

(22) PCT Filed: Apr. 8, 2022
(86) PCT No.: PCT/EP2022/059378

§ 371 Date: Oct. 12, 2023

(30) Foreign Application Priority Data
Apr. 15, 2021 (DE) 10 2021 109 459.3

(51) Int. Cl. B28D 5/00

(52) U.S. Cl. CPC B28D 5/0082

(57) ABSTRACT

A method for fixing a material block to a machining device for mechanically machining the material block, in particular to a wire saw for cutting the material block into individual wafers. In the method, the material block is adhesively bonded to an expendable workpiece carrier, and the workpiece carrier is connected to the machining device. For this purpose, the expendable workpiece carrier is provided on at least one surface with an already pre-applied layer of an adhesive that can be activated only by an external influence. The material block is then adhesively bonded to the workpiece carrier by corresponding activation of the adhesive. The method dispenses with complex steps for mixing and applying a two-component adhesive before performing machining as well as with the industrial robots used until now for this purpose. The method therefore saves time and costs in the machining process, in particular in the production of wafers.

### TECHNICAL FIELD

The present invention relates to a method for fixing a material block to a machining device for mechanically machining the material block, in particular to a wire saw for cutting the material block into individual wafers, in which the material block is adhesively bonded to an expendable workpiece carrier, and the workpiece carrier is connected to the machining device. The invention further relates to an expendable workpiece carrier, which is designed to enable the method to be carried out.

The manufacture of some products requires that material blocks undergo chipping processes to make workpieces from them, which may then be processed further. Thus for example silicon blocks are sawn into individual slices with devices called “multi wire saws” to create wafers for manufacturing solar cells. Typical dimensions of wafers of such kind are 156 mm×156 mm×180 μm. The raw material for this process is in the form of prefabricated silicon blocks with typical dimensions of 156 mm×156 mm×400 mm. In order to carry out the sawing process, these material blocks have to be fixed to the multi wire saw in a suitable way.

### PRIOR ART

When wafers are manufactured for photovoltaic systems, the material blocks are fastened to the workpiece holder of the saw with the aid of a carrier, the “expendable workpiece carrier” which is also called the beam. For this purpose, the material block is adhesively bonded to the expendable workpiece carrier, which in turn is adhesively bonded to the workpiece holder or otherwise attached to the workpiece holder. The workpiece holder is connected detachably to the wire saw, and can be detached from the saw again when the sawing process has been completed. During the sawing process, the material block is cut up into the individual wafers with a multi wire saw, wherein the saw makes comb-like incisions in the expendable workpiece carrier. Consequently, the workpiece carrier can only be used once, and is thus expendable. A procedure of such kind for producing wafers for photovoltaic cells is described in DE 10 2011 018 523 A1 for example. The sawing processes when sawing wafers for the microelectronics industry are also performed similarly.

Previously, the adhesive bonding of the material block to the expendable workpiece carrier was carried out using two-component adhesives, which in all cases have to be mixed together immediately prior to the bonding process. In most cases, special industrial robots are used for mixing and applying the adhesive, but these represent a substantial Capex and Opex burden. Moreover, processability constraints (pot life and curing time) means that only certain time windows are available, which makes it more difficult to introduce flexibility into the production workflow. Greater throughput is achieved by increasing the number of systems working in parallel.

The problem addressed by the present invention consists in reducing the proportion of unit costs associated with the mechanical machining of a material block, which must be fixed to the machining device with the aid of an expendable workpiece carrier, and increasing throughput.

### SUMMARY OF THE INVENTION

This problem is solved with the method according to claim 1. Claim 11 describes an expendable workpiece carrier which is designed for the performance of the method. Advantageous variants of the method and the workpiece carrier are subject of the dependent claims or may be discerned from the following description and the exemplary embodiment.

In the suggested method for fixing a material block to a machining device with the aid of an expendable workpiece carrier, the expendable workpiece carrier, at least one surface of which is provided with an already pre-applied layer of an adhesive that can be activated, i.e. rendered adhesive, at any time only by an external action, is provided, and the material block is then adhesively bonded to the expendable workpiece carrier by activation of the adhesive. The workpiece carrier is connected to the machining device in known manner, as will be explained in greater detail later. This connection of the workpiece carrier to the machining device may already be done before the material block is bonded to the expendable workpiece carrier, but this is preferably done after the bonding.

The pre-applied adhesive used in the suggested method is inert before its activation, so it is not suitable for creating the adhesive bond without additional external influence. In particular, the adhesive may be activated multiple times, initially when it is applied to the expendable workpiece carrier, and then later when the adhesive bond is created with the material block. The adhesive is preferably already applied as a layer to the workpiece carrier at the site of the manufacturer of the expendable workpiece carrier during or after production of the expendable workpiece carrier. The expendable workpiece carrier can then be stored for a prolonged period, e.g., several weeks or months, with the adhesive layer applied. During this time, it is permanently and immediately usable for its intended purpose. To this end, the adhesive should be sufficiently solid or correspondingly highly viscous. The adhesive may be applied to the expendable workpiece carrier in various ways, for example by spraying or rolling. With a workpiece carrier that is produced by extrusion, for example, the adhesive layer may be applied during the extrusion process.

In this context, the inventors of the suggested method discovered that the bonding method may be suitably improved in order to realise cost savings and increase throughput during the mechanical machining of a material block with the use of an expendable workpiece carrier. Through the use of a pre-applied adhesive, which becomes capable of adhesion only after or only due to additional external influence and may also be applied as a layer already when the expendable workpiece carrier is produced, the complex steps of mixing the adhesive and the usually machine-assisted application to the expendable workpiece carrier within fixed timeframes are no longer necessary. Consequently, the cost-intensive industrial robots and even stockpiling of the adhesive at the site of the machining device may be dispensed with. The expendable workpiece carriers can be delivered ready for use with the adhesive layer already applied, they are able to be stored correspondingly, and may also be cut to any size with the adhesive layer already applied thereto. The fixing of the material blocks to the expendable workpiece carrier and therewith to the machining device may then be carried out in a considerably shorter time. Thus, the process time is shortened and machining throughput increased. This in turn lowers unit costs also for the production of semiconductor wafers in the microelectronics industry, for example. The suggested technique is compatible with the conventional sawing process, and is therefore suitable for both new and existing production lines.

The adhesive which is used in the method and can only be activated by external influence is preferably an adhesive that is activated by thermal influence, in particular a hot-melt adhesive or hot glue. Other activatable adhesives may also be used, for example such as adhesives which are activated by pressure or infrared irradiation. Preferably, an adhesive is used whose adhesive strength is reduced by immersion in surrounding media (e.g., water, acids, alkalis) and/or by heat and/or the application of an electrical potential, whereby the one or more resulting workpieces may easily be separated from the expendable workpiece carrier again after machining. In order to activate an adhesive that is activated by thermal influence, the material block may first be heated and then deposited on the workpiece carrier with the adhesive layer, for example. In this context, the adhesive is activated by the heated material block and adhesive bonding takes place. The possibility also exists to place the material block on the workpiece carrier without prior heating, and then introduce both in this form into an oven or convey them through an oven, in which the adhesive layer is activated by the elevated temperature in the oven, and so effecting the adhesion. In both cases, the two parts to be connected do not necessarily have to be pressed against each other as well. The pressure applied by the dead weight of the material block is sufficient.

The expendable workpiece carrier may be made for example of glass, ceramic, graphite or plastic, preferably a composite material, e.g., a plastic with filler particles. The surface of this expendable workpiece carrier that is to be bonded adhesively to the material block is adapted to the shape of the corresponding (for bonding) surface of the material block. When sawing wafers for solar cells, the material block is cuboid, the surface of the workpiece carrier for bonding is therefore correspondingly flat. When sawing wafers for microelectronics, the material blocks are often cylindrical. In this case, the surface of the workpiece carrier for bonding is therefore curved accordingly. In the preferred variant for sawing wafers, the material block may be made for example from silicon, germanium, sapphire, quartz, glass, ceramic, silicon carbide or silicon nitride. Of course, this is not an exhaustive list.

The expendable workpiece carrier may be connected to the workpiece holder of the machining device in various ways. One option consists in bonding said workpiece carrier adhesively to the workpiece holder. For this purpose, the workpiece carrier then has a corresponding adhesive layer that can only be activated by external influence on two opposite surfaces. The expendable workpiece support is then bonded to the workpiece holder in the same way as it is to the material block on the opposite side. Another possibility is to clamp the expendable workpiece carrier into the workpiece holder, if the workpiece holder is equipped with a corresponding clamping mechanism. Other mechanical connection mechanisms are also possible.

In principle, the suggested method may be used in all applications in which an expendable workpiece carrier that must inevitably be damaged as a consequence of the manufacturing process is needed for fixing a material block that is to be machined to a machining device. Examples particularly include chipping machining techniques such as sawing, cutoff grinding or milling. In the preferred application, however, the suggested method is adopted for use in multi wire saws in order to separate the material block into a multiplicity of wafers. The primary application area is therefore the production of wafers in the photovoltaic and microelectronics industry.

### BRIEF DESCRIPTION OF THE DRAWINGS

In the following text, the suggested method will be explained again with reference to an exemplary embodiment in conjunction with the drawings. In the drawing:

FIG. 1 is a schematic side view of the material bond when sawing wafers in a multi wire saw; and

FIG. 2 is a schematic representation of the layer structure of an expendable workpiece carrier according to the present invention before connection to the material block and the workpiece holder.

### WAYS OF IMPLEMENTING THE INVENTION

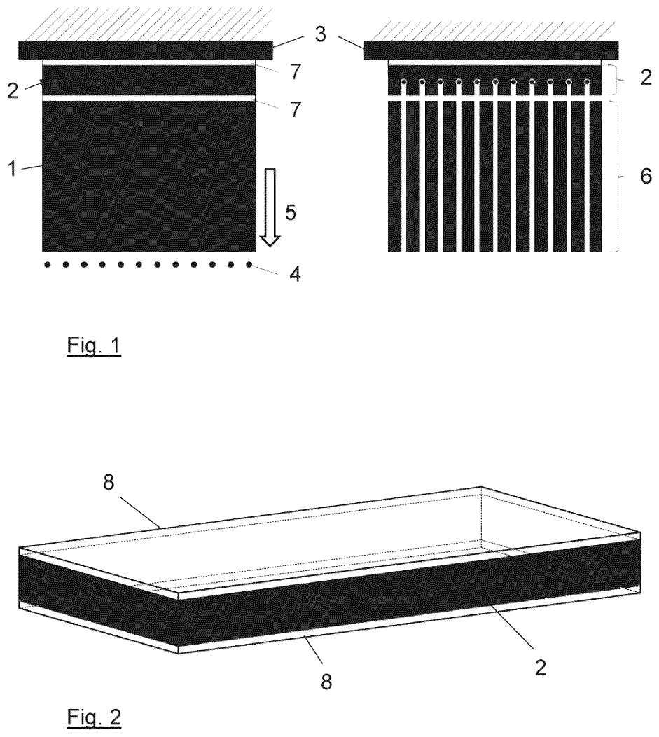

In the following text, the suggested method will be explained with reference to an exemplary embodiment in which individual wafers are produced from a material block using a multi wire saw. A multi wire saw of such kind is used for sawing silicon blocks for the manufacture of solar cells, for example. In this context, an array of parallel wires arranged in the saw separates the silicon block into wafers in known manner. FIG. 1 shows a schematic side view of this process. The diagram in the subfigure on the left depicts the material block 1 that is to be sawn connected to a workpiece holder 3 of the multi wire saw by an expendable workpiece carrier 2. The individual saw wires 4 appear at the bottom of this subfigure. They extend in the sectional plane illustrated and during the sawing process they are moved back and forth in this direction. At the same time, the workpiece holder 3 with the material block 1 attached is moved in feed direction 5. The workpiece holder 3 is clamped in positive locking manner in the saw machine. After the sawing operation is complete, the material block 1 has been divided into the individual wafers 6, as is shown in the subfigure on the right in FIG. 1. The expendable workpiece carrier 2 has been cut in a comb-like pattern in the course of this sawing process, as is also visible in the figure. In the present example, the expendable workpiece carrier 2 is connected to the material block 1 and the workpiece holder 3 via adhesive layers 7. After the sawing process has been carried out, these adhesive layers, whose adhesive strength has been diminished by external media such as water, acid, alkalis or heat, for example, are released, allowing the expendable workpiece carrier 2 to be detached from the wafers 6 and the workpiece holder 3.

In the suggested method, this adhesive bonding of the expendable workpiece carrier 2 to the workpiece holder 3 and the material block 1 is realised differently from the manner implemented in wafer manufacturing according to the current state of the art. According to the present invention, the expendable workpiece carrier 2 is provided with adhesive layers 8 already pre-applied, as is indicated schematically in FIG. 2. In this example, the expendable workpiece carrier 2 is made from a composite material (polymer and inorganic non-metal). An activatable adhesive which is only activated by suitable methods (external influence) to create an adhesive bond is applied as the pre-applied adhesive layer. In the present example, a water-soluble, heat-activatable adhesive is applied to both surfaces of the expendable workpiece carrier 2 (beam). The user activates the adhesive with a heat source, the bond may be released without residue after sawing in a heated water bath. The adhesive layer may already be applied during or after production of the beam by the beam manufacturer. In this way, several manufacturing steps, including the machinery required therefor, may be dispensed with.

### LIST OF REFERENCE NUMERALS

1 Material block
2 Expendable workpiece carrier or beam
3 Workpiece holder
4 Saw wires
5 Feed direction
6 Wafer
7 Adhesive layers
8 Activatable adhesive layer

1. Method for fixing a material block to a machining device for mechanically machining the material block, in which the material block is adhesively bonded to an expendable workpiece carrier, and the workpiece carrier is connected to the machining device,
characterized in that
the expendable workpiece carrier is provided on at least one surface thereof with a pre-applied layer of an adhesive that can only be activated by external influence, and the material block is adhesively bonded to the workpiece carrier by activation of the adhesive.

2. Method according to claim 1,
characterized in that
an adhesive that can be activated by the influence of heat and/or the application of pressure is used as the activatable adhesive.

3. Method according to claim 1,
characterized in that
the activatable adhesive is chosen such that the expendable workpiece carrier can be stored with the pre-applied layer of the activatable adhesive for a period of several weeks or months before use without losing its activatable adhesive function.

4. Method according to claim 1,
characterized in that
a hot-melt adhesive is used as the activatable adhesive.

5. Method according to claim 1,
characterized in that
the expendable workpiece carrier is or can be stored with the pre-applied layer of the activatable adhesive for several weeks before the material block is adhesively bonded to the workpiece carrier by activation of the adhesive.

6. Method according to claim 1,
characterized in that
the expendable workpiece carrier is clamped into a workpiece holder of the machining device.

7. Method according to claim 1,
characterized in that
the expendable workpiece carrier is provided with the pre-applied layer of the activatable adhesive on two opposite surfaces, and the workpiece carrier is adhesively bonded into the workpiece holder of the machining device by activation of the adhesive.

8. Method according to claim 1 for fixing a material block to a wire saw for cutting the material block into individual wafers or small material block fragments.

9. Method according to claim 8 for fixing a material block made from silicon, germanium, sapphire, quartz, glass, ceramic, silicon carbide or silicon nitride.

10. Method according to claim 1,
characterized in that
the expendable workpiece carrier is provided from a composite material.

11. Workpiece carrier which is suitable for use as the expendable workpiece carrier for fixing a material block to a wire saw for cutting the material block into individual wafers and which has a pre-applied layer of an adhesive that can only be activated by external influence on at least one surface.

12. Workpiece carrier according to claim 11,
characterized in that
the activatable adhesive is an adhesive that can be activated by thermal influence and/or by the application of pressure.

13. Workpiece carrier according to claim 11,
characterized in that
the activatable adhesive is a hot-melt adhesive.

14. Workpiece carrier according to claim 11,
characterized in that
the workpiece carrier is furnished with the pre-applied layer of the adhesive that can only be activated by external influence on two opposite surfaces.
